(19) United States
(12) Patent Application Publication
(10) Pub. No.: US 2013/0264582 A1
(43) Pub. Date: Oct. 10, 2013

(54) SILICON CARBIDE SEMICONDUCTOR DEVICE AND METHOD FOR MANUFACTURING THE SAME

(71) Applicant: SUMITOMO ELECTRIC INDUSTRIES, LTD, Osaka-shi (JP)

(72) Inventor: Hideki Hayashi, Osaka-shi (JP)

(73) Assignee: Sumitomo Electric Industries, Ltd, Osaka-shi (JP)

(21) Appl. No.: 13/770,604

(22) Filed: Feb. 19, 2013

Related U.S. Application Data
(60) Provisional application No. 61/621,768, filed on Apr. 9, 2012.

(30) Foreign Application Priority Data
Apr. 9, 2012 (JP) 2012-088211

(51) Int. Cl. H01L 29/16; H01L 29/66

(52) U.S. Cl. CPC H01L 29/1608; H01L 29/66712
USPC 257/77; 438/270

(57) ABSTRACT

A trench having a sidewall is provided on a first face of a silicon carbide substrate of a first conductivity type. A first region of a second conductivity type is provided on the first face. A second region is provided on the first region, and is separated from the silicon carbide substrate by the first region. The second region is of the first conductivity type. A charge compensation region is provided on the sidewall of the trench. The charge compensation region is of the second conductivity type. A gate insulation film is provided on the first face and above the first region. A first main electrode is provided on the first region. A second main electrode is provided on a second face of the silicon carbide substrate.

### BACKGROUND OF THE INVENTION

1. Field of the Invention

The present invention relates to a silicon carbide semiconductor device and a method for manufacturing a silicon carbide semiconductor device.

2. Description of the Background Art

Some power semiconductor devices employing a silicon (Si) semiconductor have the so-called superjunction structure to improve the tradeoff between low ON resistance and high breakdown voltage. This structure is disclosed by, for example, G. Deboy et al. in “A new generation of high voltage MOSFETs breaks the limit line of Silicon”, IEDM Tech. Dig. (1998), pp. 683-685 (Non Patent Literature 1). According to this document, a diffusion step is employed in manufacturing a superjunction structure.

To further improve the aforementioned tradeoff, a study is made to employ a wide bandgap semiconductor such as a silicon carbide (SiC) semiconductor, instead of a Si semiconductor. In this case, the method set forth in the aforementioned document is not necessarily suitable for SiC semiconductors since impurity diffusion does not readily occur in SiC, differing from Si.

### SUMMARY OF THE INVENTION

The present invention is directed to solving the aforementioned problem. An object is to further improve the tradeoff between low ON resistance and high breakdown voltage at a silicon carbide semiconductor device.

A silicon carbide semiconductor device of the present invention includes a silicon carbide substrate, a first region, a second region, a charge compensation region, a gate insulation film, a gate electrode, a first main electrode, and a second main electrode. The silicon carbide substrate is of a first conductivity type. The silicon carbide substrate has a first face, and a second face opposite to the first face. On the first face, a trench having a sidewall is provided. The first region is provided on the first face of the silicon carbide substrate. The first region is of a second conductivity type differing from the first conductivity type. The second region is provided on the first region. The second region is separated from the silicon carbide substrate by the first region. The second region is of the first conductivity type. The charge compensation region is provided on the sidewall of the trench. The charge compensation region is of the second conductivity type. The gate insulation film is provided on the first face, and above the first region. The gate electrode is provided on the gate insulation film. The first main electrode is provided on the first region. The second main electrode is provided on the second face.

According to the present device, a superjunction structure is provided by the charge compensation region. Thus, the tradeoff between a low ON resistance and high breakdown voltage can be improved.

The charge compensation region is formed at the sidewall of the trench. By providing a trench corresponding to the depth of the superjunction structure, a deep superjunction structure can be readily implemented.

Preferably, the trench has a bottom, and the charge compensation region includes a region on the bottom. Accordingly, the breakdown voltage of the semiconductor device can be further increased.

Preferably, the first region and the charge compensation region are connected. Accordingly, the potential of the charge compensation region can be stabilized.

The silicon carbide semiconductor device may include a filler filling the trench. The first main electrode may include a region on the filler. This facilitates formation of the first main electrode.

The trench may include a cavity inside. Accordingly, the step of filling the trench can be omitted.

Preferably, the first face includes a {0-33-8} plane at least partially. Accordingly, the channel resistance can be reduced. Therefore, the ON resistance of the semiconductor device can be reduced.

A method for manufacturing a silicon carbide semiconductor device of the present invention includes the following steps. A silicon carbide substrate of a first conductivity type including a first face and a second face opposite to the first face is prepared. On the first face of the silicon carbide substrate, a trench having a sidewall is formed. On the sidewall of the trench, a charge compensation region of a second conductivity type differing from the first conductivity type is formed. On the first face of the silicon carbide substrate, a first region of the second conductivity type is formed. On the first region, a second region of the first conductivity type is formed, separated from the silicon carbide substrate by the first region. On the first face, a gate insulation film is formed above the first region. On the gate insulation film, a gate electrode is formed. On the first region, a first main electrode is formed. On the second face, a second main electrode is formed.

According to the manufacturing method, a charge compensation region for providing a superjunction structure is formed at the sidewall of the trench. Therefore, by providing a trench corresponding to the depth of the superjunction structure, a deep superjunction structure can be readily implemented.

After the charge compensation region is formed, the charge compensation region located on the first face may be removed. Accordingly, the region of the charge compensation region not required is removed. In the case where the charge compensation region located on the first face is removed, polishing may be carried out on the first face. Accordingly, the surface can be planarized. Prior to this polishing, the trench may be filled. Accordingly, excessive polishing of the first face of the silicon carbide substrate in the proximity of the trench can be suppressed.

In forming a charge compensation region, silicon carbide of the second conductivity type may be grown epitaxially. Accordingly, the charge compensation region can be formed by epitaxial-growth.

In forming a charge compensation region, impurity ions directed to doping of the second conductivity type may be implanted on the sidewall of the trench. Accordingly, the charge compensation region can be formed by ion implantation.

According to the present invention, the tradeoff between low ON resistance and high breakdown voltage can be further improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial sectional view schematically representing a configuration of a silicon carbide semiconductor device according to a first embodiment of the present invention.

FIG. 2 is a partial sectional view schematically representing a first step in a method for manufacturing the silicon carbide semiconductor device of FIG. 1.

FIG. 3 is a partial sectional view schematically representing a second step in the method for manufacturing the silicon carbide semiconductor device of FIG. 1.

FIG. 4 is a partial sectional view schematically representing a third step in the method for manufacturing the silicon carbide semiconductor device of FIG. 1.

FIG. 5 is a partial sectional view schematically representing a fourth step in the method for manufacturing the silicon carbide semiconductor device of FIG. 1.

FIG. 6 is a partial sectional view schematically representing a fifth step in the method for manufacturing the silicon carbide semiconductor device of FIG. 1. FIG. 7 is a partial sectional view schematically representing a sixth step in the method for manufacturing the silicon carbide semiconductor device of FIG. 1.

FIG. 8 is a partial sectional view schematically representing a seventh step in the method for manufacturing the silicon carbide semiconductor device of FIG. 1.

FIG. 9 is a partial sectional view schematically representing an eighth step in the method for manufacturing the silicon carbide semiconductor device of FIG. 1.

FIG. 10 is a partial sectional view schematically representing a ninth step in the method for manufacturing the silicon carbide semiconductor device of FIG. 1.

FIG. 11 is a partial sectional view schematically representing a tenth step in the method for manufacturing the silicon carbide semiconductor device of FIG. 1.

FIG. 12 is a partial sectional view representing a modification of FIG. 4.

FIG. 13 is a partial sectional view schematically representing a configuration of a silicon carbide semiconductor device according to a second embodiment of the present invention.

FIG. 14 is a partial sectional view representing an example of a channel face of the first or second embodiment of the present invention.

### DESCRIPTION OF THE PREFERRED EMBODIMENTS

Embodiments of the present invention will be described hereinafter based on the drawings. In the following drawings, the same or corresponding elements have the same reference characters allotted, and description thereof will not be repeated. As to the crystallographic notation in the present specification, a specific plane is represented by ( ) whereas a group of equivalent planes is represented by { }. For a negative index, a bar (−) is typically allotted above a numerical value in the crystallographic aspect. However, in the present specification, a negative sign will be attached before the numerical value.

### First Embodiment

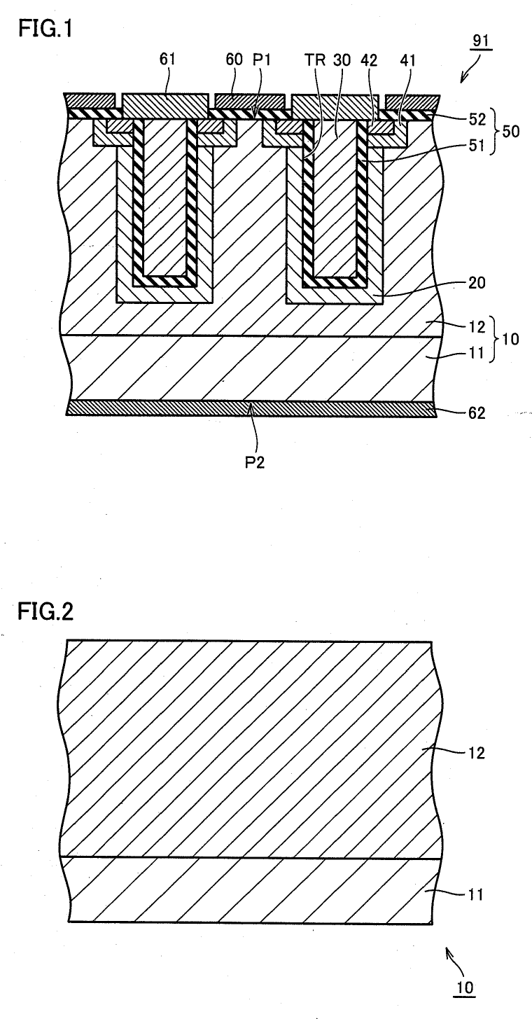

As shown in FIG. 1, an MOSFET 91 (silicon carbide semiconductor device) of the present embodiment includes an epitaxial substrate 10 (silicon carbide substrate), a p body region 41, an n region 42, a charge compensation region 20, a filler 30, an insulation film 50, a gate electrode 60, a source electrode 61 (first main electrode), and a drain electrode 62 (second main electrode). Insulation film 50 includes a trench insulation film 51 and a gate insulation film 52.

Epitaxial substrate 10 is made of silicon carbide, and is of the n type (first conductivity type). Epitaxial substrate 10 includes a single crystal substrate 11, and an n drift layer 12 (epitaxial layer) provided thereon. Epitaxial substrate 10 includes an upper face P1 (first face) and a lower face P2 (second face opposite to the first face). Upper face P1 is located at the side of n drift layer 12, whereas lower face P2 is located at the side of single crystal substrate 11. Preferably, upper face P1 includes a {0-33-8} plane at least partially.

On upper face P1, a trench TR having a sidewall is provided. The sidewall constitutes at least a portion of the inner face of trench TR. In the present embodiment, a bottom is provided as a portion of the inner face. The inner face of trench TR is covered with trench insulation film 51. Trench TR is filled by filler 30. Filler 30 is made of polysilicon, for example.

P body region 41 is of the p type (a second conductivity type differing from the first conductivity type). P body region (41 (first region) is provided on upper face P1 of epitaxial substrate 10. P body region 41 and charge compensation region 20 are connected.

N region 42 is of the n type. N region 42 (second region) is provided on p body region 41. N region 42 is separated from epitaxial substrate 10 by p body region 41.

Charge compensation region 20 is of the p type. Charge compensation region 20 is provided on the sidewall of trench TR. Preferably, charge compensation region 20 is also provided on the bottom face of trench TR.

Gate insulation film 52 is provided on upper face P1, and above p body region 41. Gate insulation film 52 is formed of a silicon oxide film, for example. Gate electrode 60 is provided on gate insulation film 52.

Source electrode 61 is an ohmic electrode provided on p body region 41. Source electrode 61 includes a region on filler 30. Drain electrode 62 is an ohmic electrode provided on lower face P2.

A method for manufacturing MOSFET 91 will be described hereinafter.

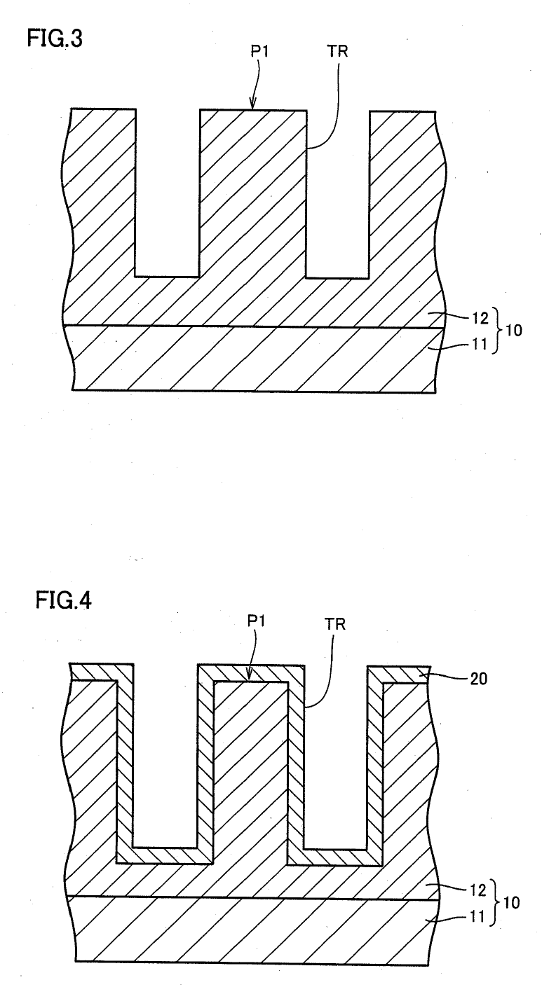

As shown in FIG. 2, epitaxial substrate 10 is prepared. Specifically, n drift layer 12 is formed by epitaxial-growth on single crystal substrate 11. This formation is carried out by CVD, for example.

As shown in FIG. 3, trench TR having a sidewall is formed on upper face P1 of epitaxial substrate 10. Formation of trench TR is carried out by dry etching using a mask (not shown), for example.

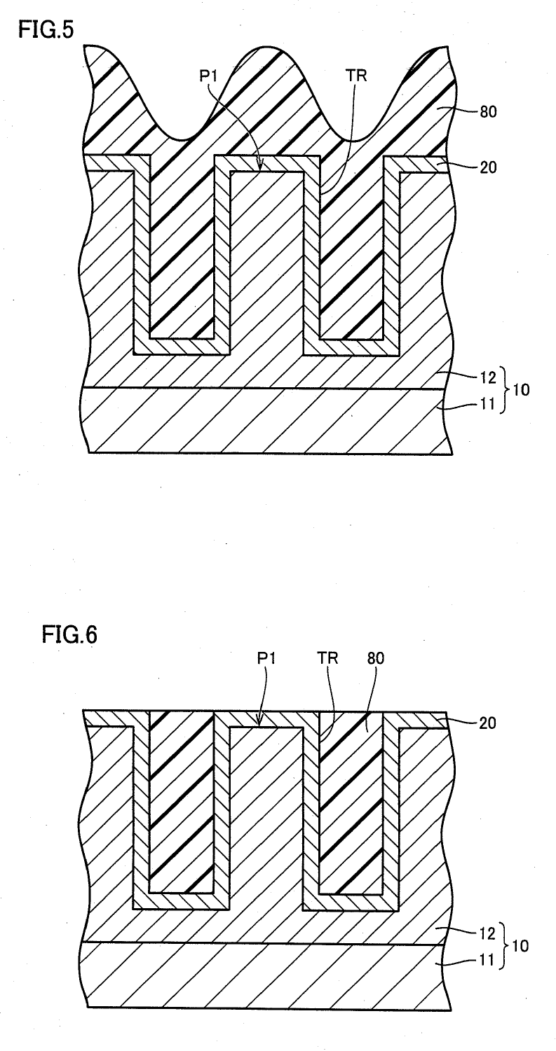

As shown in FIG. 4, charge compensation region 20 of the p type is formed on the inner face of trench TR. In the present embodiment, this formation is carried out by epitaxially growing silicon carbide of the p type. This epitaxial-growth is carried out by CVD, for example.

As shown in FIG. 5, trench TR is filled with provisional filler 80. Provisional filler 80 is preferably formed by applying and curing a liquid material. Provisional filler 80 is made of polymide, for example.

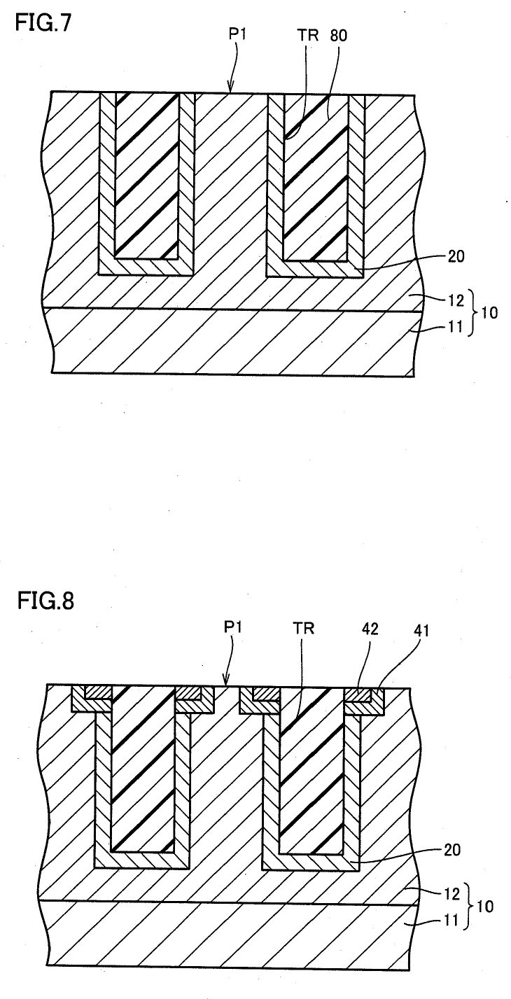

As shown in FIGS. 6 and 7, polishing is conducted on upper face P1. Accordingly, charge compensation region 20 located on upper face P1 is removed. This polishing is carried out by CMP, for example.

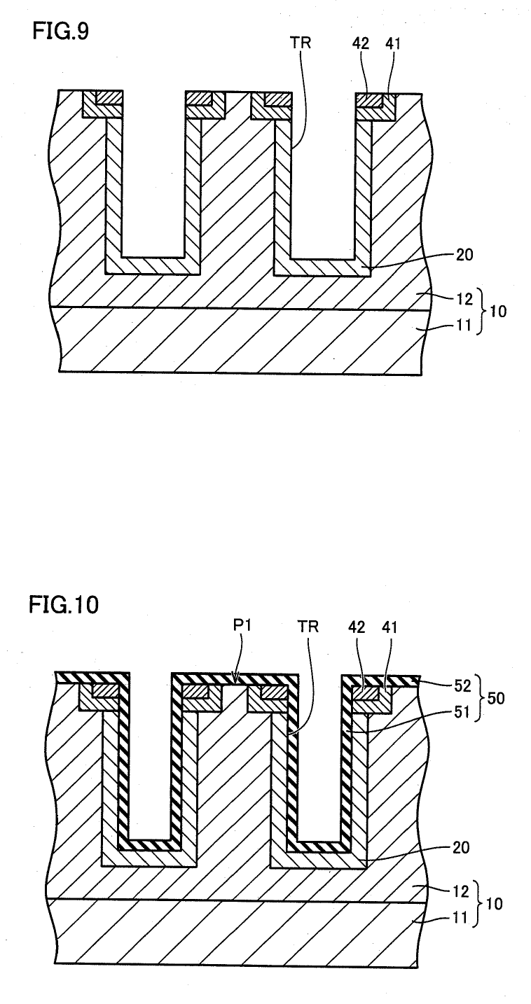

As shown in FIG. 8, p body region 41 and n region 42 are formed on upper face P1 of epitaxial substrate 10. Then, provisional filler 80 is removed (FIG. 9). Next, thermal treatment to render conductivity type impurities active is carried out.

As shown in FIG. 10, insulation film 50 is formed. Accordingly, gate insulation film 52 is formed on upper face P1 and above p body region 41. Also, trench insulation film 51 is formed

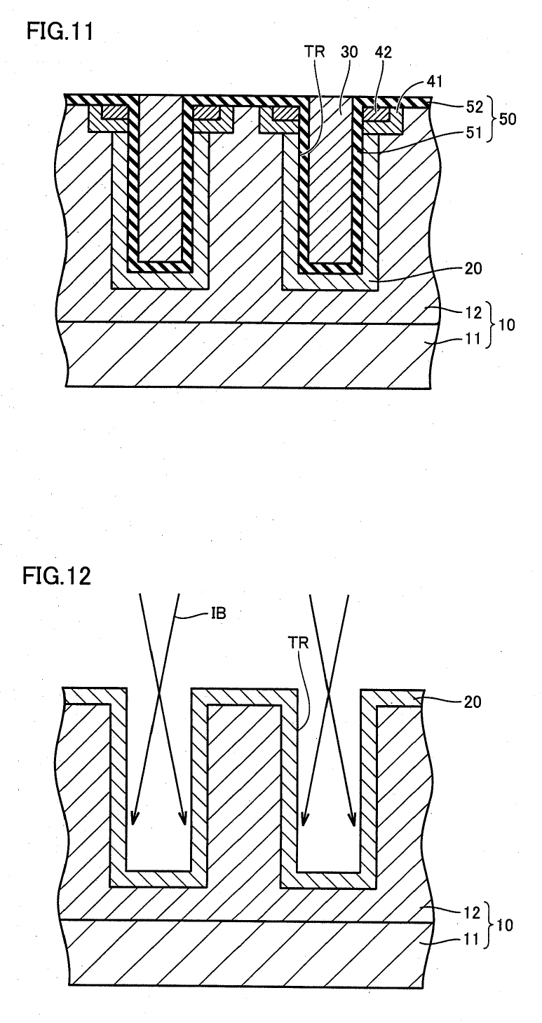

As shown in FIG. 11, trench TR is filled with filler 30.

Referring to FIG. 1 again, gate electrode 60 is formed on gate insulation film 52. Source electrode 61 is formed on p body region 41. Further, drain electrode 62 is formed on lower face P2. Thus, MOSFET 91 is obtained.

According to the present embodiment, a superjunction structure is implemented by virtue of charge compensation region 20, as shown in FIG. 1. Accordingly, the tradeoff between low ON resistance and high breakdown voltage can be improved.

Charge compensation region 20 is located at the sidewall of trench TR. Therefore, a deep superjunction structure can be readily implemented by providing trench TR corresponding to the depth of superjunction structure.

Trench TR has a bottom, and charge compensation region 20 includes a region on the bottom. Accordingly, the breakdown voltage of MOSFET 91 can be further increased.

P body region 41 is connected with charge compensation region 20. Accordingly, the potential of charge compensation region 20 can be stabilized.

Source electrode 61 may include a region located on filler 30. Accordingly, formation of source electrode 61 is facilitated. In this case, source electrode 61 on and traversing trench TR may be provided, as shown in FIG. 1. Preferably, upper face P1 includes a {0-33-8} plane at least partially.

Accordingly, the channel resistance can be reduced. Thus, the ON resistance of MOSFET 91 can be reduced.

In the method for manufacturing MOSFET 91, charge compensation region 20 located on upper face P1, after being formed as shown in FIG. 4, is removed, as shown in FIG. 7. Accordingly, the region of charge compensation region 20 not required is removed. When charge compensation region 20 located on upper face P1 is removed, polishing is carried out on upper face P1. Accordingly, the surface can be planarized. Thus, trench TR is filled by provisional filler 80 (FIG. 5) prior to polishing. Accordingly, excessive polishing of upper face P1 of epitaxial substrate 10 in the proximity of trench TR can be suppressed.

In the formation of charge compensation region 20, silicon carbide of the p type is grown epitaxially. Accordingly, charge compensation region 20 can be formed by epitaxial-growth.

### Second Embodiment

Referring to FIG. 12, in the formation of charge compensation region 20 of the present embodiment, impurity ions for the doping of the p type are implanted onto the inner face of trench TR, as indicated by arrow IB in FIG. 12, instead of the epitaxial-growth (FIG. 4). Accordingly, charge compensation region 20 can be formed by ion implantation. The impurity ion is, for example, Al ion. The direction of the ion beam is oblique, as shown in FIG. 12. The angle of the ion beam is selected so as to reach, not only the sidewall of trench TR, but also the bottom.

The elements of the structure other than those set forth above are substantially identical to those of the above-described first embodiment. Therefore, the same or corresponding elements have the same reference characters allotted, and description thereof will not be repeated.

### Third Embodiment

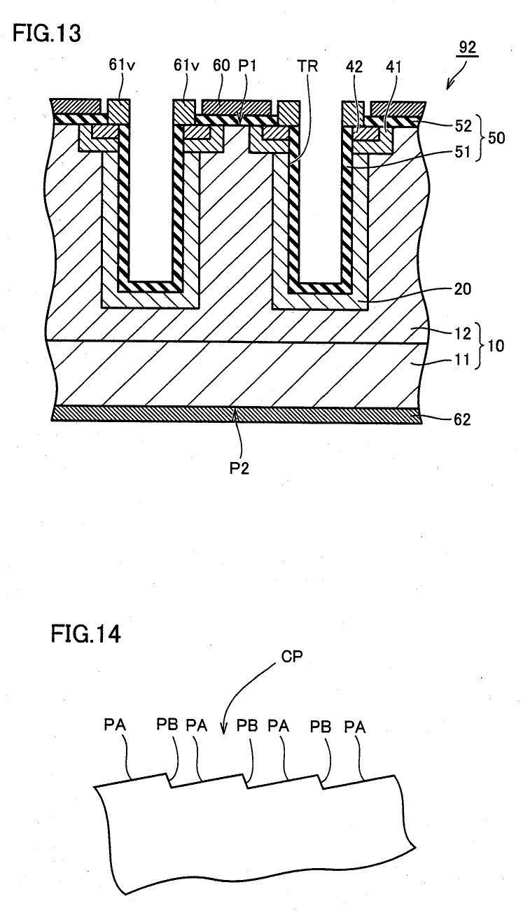

As shown in FIG. 13, trench TR of MOSFET 92 (silicon carbide semiconductor device) of the present embodiment includes a cavity inside. In other words, filler 30 (FIG. 1) is not provided. MOSFET 92 includes a source electrode 61v. Source electrode 61v is not located on trench TR.

The elements of the structure other than those set forth above are substantially identical to those of the above-described first embodiment. Therefore, the same or corresponding elements have the same reference characters allotted, and description thereof will not be repeated.

According to the present embodiment, the step of forming filler 30 (FIG. 1) can be omitted while avoiding the arrangement of a source electrode above a cavity.

Filler 30 (FIG. 1) may be added to the configuration of the present embodiment.

### Appendix

Upper face P1 in each of the embodiments set forth above may be a composite plane CP (FIG. 14) having a specific plane orientation partially. As used herein, a specific plane orientation is the {0-33-8} plane, more specifically, any of the (0-33-8) plane, (30-3-8) plane, (-330-8) plane, (03-3-8) plane, (-303-8) plane, and (3-30-8) plane. Composite plane CP is a plane including, when viewed microscopically, a portion PA and a portion PB having a plane orientation differing from that of portion PA. As used herein, “microscopically” implies taking into account the dimension of approximately interatomic spacing. For example, each of portions PA and PB may have a width dimension approximately two times the interatomic spacing in the aligning direction (periodic direction) of adjacent portions PA and PB, and a dimension sufficiently greater than the interatomic spacing in the direction crossing the periodic direction.

Furthermore, a configuration may be employed in which the n type and p type set forth in each of the embodiments are interchanged. In this case, MOSFET 91 or 92 is of the p channel type, not the n channel type. Moreover, an MISFET may be used instead of MOSFET.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device comprising:
a silicon carbide substrate of a first conductivity type, including a first face and a second face opposite to said first face, a trench having a sidewall being provided on said first face; and
a first region of a second conductivity type differing from said first conductivity type, provided on said first face of said silicon carbide substrate;
a second region of said first conductivity type, provided on said first region and separated from said silicon carbide substrate by said first region;
a charge compensation region of said second conductivity type, provided on said sidewall of said trench;
a gate insulation film provided on said first face, and above said first region;
a gate electrode provided on said gate insulation film;
a first main electrode provided on said first region; and
a second main electrode provided on said second face.

2. The silicon carbide semiconductor device according to claim 1, wherein said trench has a bottom, and said charge compensation region includes a region on said bottom.

3. The silicon carbide semiconductor device according to claim 1, wherein said first region and said charge compensation region are connected.

4. The silicon carbide semiconductor device according to claim 1, further comprising a filler filling said trench,
wherein said first electrode includes a region above said filler.

5. The silicon carbide semiconductor device according to claim 1, wherein said trench includes a cavity inside.

6. The silicon carbide semiconductor device according to claim 1, wherein said first face includes a {0-33-8} plane at least partially.

7. A method for manufacturing a silicon carbide semiconductor device, comprising the steps of:
preparing a silicon carbide substrate of a first conductivity type, having a first face and a second face opposite to said first face, forming a trench having a sidewall, on said first face of said silicon carbide substrate;
forming a charge compensation region of a second conductivity type differing from said first conductivity type, on said sidewall of said trench;
forming a first region of said second conductivity type, on said first face of said silicon carbide substrate;
forming a second region of said first conductivity type, on said first region and separated from said silicon carbide substrate by said first region;
forming a gate insulation film on said first face and above said first region;
forming a gate electrode on said gate insulation film;
forming a first main electrode on said first region; and
forming a second main electrode on said second face.

8. The method for manufacturing a silicon carbide semiconductor device according to claim 7, further comprising the step of removing said charge compensation region located on said first face, after said step of forming a charge compensation region.

9. The method for manufacturing a silicon carbide semiconductor device according to claim 8, wherein said step of removing said charge compensation region located on said first face includes the step of carrying out polishing on said first face.

10. The method for manufacturing a silicon carbide semiconductor device according to claim 9, wherein said step of removing said charge compensation region located on said first face includes the step of filling said trench prior to said step of carrying out polishing.

11. The method for manufacturing a silicon carbide semiconductor device according to claim 7, wherein said step of forming a charge compensation region includes the step of epitaxially growing silicon carbide of said second conductivity type.

12. The method for manufacturing a silicon carbide semiconductor device according to claim 7, wherein said step of forming a charge compensation region includes the step of implanting impurity ions for doping of said second conductivity type on said sidewall of said trench.
